(19) United States
(12) Patent Application Publication
(10) Pub. No.: US 2024/0047408 A1
(43) Pub. Date: Feb. 8, 2024

(54) SEMICONDUCTOR PACKAGE WITH A STACKED FILM STRUCTURE TO REDUCE CRACKING AND DELAMINATION AND METHODS OF MAKING THE SAME

(71) Applicant: Taiwan Semiconductor Manufacturing Company Limited, Hsinchu (TW)

(72) Inventors: Amram Eitan, Hsinchu (TW); Wen-Yi Lin, New Taipei City (TW); Teng-Yuan Lo, Hsinchu (TW)

(21) Appl. No.: 17/882,655

(22) Filed: Aug. 8, 2022

(51) Int. Cl. H01L 23/00; H01L 25/065

(52) U.S. Cl. CPC H01L 24/73; H01L 24/05; H01L 24/48; H01L 25/0657; H01L 2224/73265; H01L 2224/48091; H01L 2924/35121

(57) ABSTRACT

An embodiment semiconductor device may include an electrical interconnect layer, a bonding pad electrically coupled to the electrical interconnect layer, a stacked film structure including a first film partially covering a surface of the bonding pad and a second film partially covering the first film, a first aperture formed in the first film over a portion of the surface of the bonding pad, a second aperture formed in the second film such that the second aperture is larger than the first aperture and is formed over the first aperture such that the first aperture is located entirely below an area of the second aperture, and a solder material portion formed in contact with the bonding pad. The solder material portion may include a first width that is less than a size of the second aperture such that the solder material portion does not contact the second film.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds or thousands of integrated circuits are typically manufactured on a single semiconductor wafer, and individual dies on the wafer are singulated by sawing between the integrated circuits along scribe lines. The individual dies are typically packaged separately, in multi-chip modules, or in other types of packaging, for example.

In addition to smaller electronic components, improvements to the packaging of components have been developed to provide smaller packages that occupy less area than previous packages. Example approaches include quad flat pack (QFP), pin grid array (PGA), ball grid array (BGA), flip chips (FC), 3-dimensional integrated circuits (3DICs), wafer level packages (WLPs), package on package (PoP), System on Chip (SoC) or System on Integrated Circuit (SoIC) devices. Some of these 3-dimensional devices (e.g., 3DIC, SoC, SoIC) are prepared by placing chips over chips on a semiconductor wafer level. These 3-dimensional devices provide improved integration density and other advantages, such as faster speeds and higher bandwidth, because of the decreased length of interconnects between the stacked chips. However, there are many challenges related to fabricating and operating 3-dimensional devices.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a related semiconductor device.

FIG. 1B is an enlarged vertical cross-sectional view of a portion of the related semiconductor device of FIG. 1A.

FIG. 2A is a vertical cross-sectional view of a portion of a semiconductor device having improved mechanical properties, according to various embodiments.

FIG. 2B is a horizontal cross-sectional view of the portion of the semiconductor device of FIG. 2A, according to various embodiments.

FIG. 3A is a vertical cross-sectional view of an intermediate structure that may be used in the formation of a bonding structure, according to various embodiments.

FIG. 3B is a vertical cross-sectional view of a further intermediate structure that may be used in the formation of a bonding structure, according to various embodiments.

FIG. 3C is a vertical cross-sectional view of a further intermediate structure that may be used in the formation of a bonding structure, according to various embodiments.

FIG. 3D is a vertical cross-sectional view of a further intermediate structure that may be used in the formation of a bonding structure, according to various embodiments.

FIG. 3E is a vertical cross-sectional view of a further intermediate structure that may be used in the formation of a bonding structure, according to various embodiments.

FIG. 4 is a vertical cross-sectional view of an intermediate structure that may be used in the formation of a semiconductor device, according to various embodiments.

FIG. 5 is a vertical cross-sectional view of a further intermediate structure that may be used in the formation of a semiconductor device, according to various embodiments.

FIG. 6 is a vertical cross-sectional view of a further intermediate structure that may be used in the formation of a semiconductor device, according to various embodiments.

FIG. 7 is a vertical cross-sectional view of a further intermediate structure that may be used in the formation of a semiconductor device, according to various embodiments.

FIG. 8 is a vertical cross-sectional view of a further intermediate structure that may be used in the formation of a semiconductor device, according to various embodiments.

FIG. 9 is a vertical cross-sectional view of a further intermediate structure that may be used in the formation of a semiconductor device, according to various embodiments.

FIG. 10 is a vertical cross-sectional view of a further intermediate structure that may be used in the formation of a semiconductor device, according to various embodiments.

FIG. 11 is a vertical cross-sectional view of a further intermediate structure that may be used in the formation of a semiconductor device, according to various embodiments.

FIG. 12 is a vertical cross-sectional view of a further intermediate structure that may be used in the formation of a semiconductor device, according to various embodiments.

FIG. 13 is a vertical cross-sectional view of a further intermediate structure that may be used in the formation of a semiconductor device, according to various embodiments.

FIG. 14 is a vertical cross-sectional view of a further intermediate structure that may be used in the formation of a semiconductor device, according to various embodiments.

FIG. 15 is a vertical cross-sectional view of a further intermediate structure that may be used in the formation of a semiconductor device, according to various embodiments.

FIG. 16 is a vertical cross-sectional view of a further intermediate structure that may be used in the formation of a semiconductor device, according to various embodiments.

FIG. 17 is a vertical cross-sectional view of a further intermediate structure that may be used in the formation of a semiconductor device, according to various embodiments.

FIG. 18 is a vertical cross-sectional view of a further intermediate structure that may be used in the formation of a semiconductor device, according to various embodiments.

FIG. 19A is a vertical cross-sectional view of a semiconductor device, according to various embodiments.

FIG. 19B is a vertical cross-sectional view of a further semiconductor device, according to various embodiments.

FIG. 20 is a flowchart illustrating operations of a method of forming a bonding structure for a semiconductor device, according to various embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, this disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Typically, in a semiconductor package, several semiconductor integrated circuit (IC) dies (i.e., “chips”) may be mounted onto a common substrate, which may also be referred to as a “package substrate.” In some embodiments, electrical connections to the semiconductor package may be made by mounting the package substrate onto a support substrate containing electrical interconnects, such as a printed circuit board (PCB). A semiconductor package may further include an interposer to which one or more semiconductor dies may be attached and electrically coupled. The interposer, in turn, may be attached and electrically coupled to a package substrate, which may be further attached to a PCB. As such, separate structures (e.g., semiconductor dies, interposer, package substrate, and PCB) may be fabricated and then assembled.

Various embodiments disclosed herein may include a package bonding structure that includes a multi-layer film structure that may reduce or mitigate cracking and delamination caused by differences in coefficients of thermal expansion between various components of the bonding structure. In this regard, a solder material portion may electrically and mechanically couple a bonding pad of a first package with a bonding pad of a second package. A first film may partially cover the bonding pad of the first package and may be in contact with the solder material portion. A second film may provide mechanical strength to the first package but may be configured to not contact the solder material portion. Rather, an underfill material portion may be formed between the second film and the solder material portion. Such a configuration may reduce various thermally induced stresses and strains within the bonding structure and may thereby reduce or mitigate cracking and delamination.

An embodiment semiconductor device may include an electrical interconnect layer, a bonding pad electrically coupled to the electrical interconnect layer, a stacked film structure including a first film partially covering a surface of the bonding pad and a second film partially covering the first film, a first aperture formed in the first film over a portion of the surface of the bonding pad, a second aperture formed in the second film such that the second aperture is larger than the first aperture and is formed over the first aperture such that the first aperture is located entirely below an area of the second aperture, and a solder material portion formed in contact with the bonding pad. The solder material portion may include a first width that is less than a size of the second aperture such that the solder material portion does not contact the second film.

A further embodiment semiconductor device may include a first semiconductor package including a first semiconductor die and a first bonding pad electrically coupled to the first semiconductor die; a second semiconductor package including a second semiconductor die and a second bonding pad electrically coupled to the second semiconductor die; and a solder material portion electrically connecting the first bonding pad of the first semiconductor package to the second bonding pad of the second semiconductor package. The first semiconductor package may further include a stacked film structure including a first film partially covering a surface of the first bonding pad and a second film partially covering the first film, such that the second film is separated from the solder material portion.

A disclosed method of forming a bonding structure for a semiconductor device, may include forming a first film over a bonding pad of an electrical interconnect layer; forming a second film over the first film; forming a first aperture in the first film and a second aperture in the second film such that the first aperture exposes a portion of the bonding pad, and the second aperture is formed over the first aperture such that the first aperture is located entirely below an area of the second aperture. The method may further include forming a solder material portion that is in contact with the bonding pad but is separated from the second film and forming an underfill material portion between the solder material portion and an edge of the second aperture.

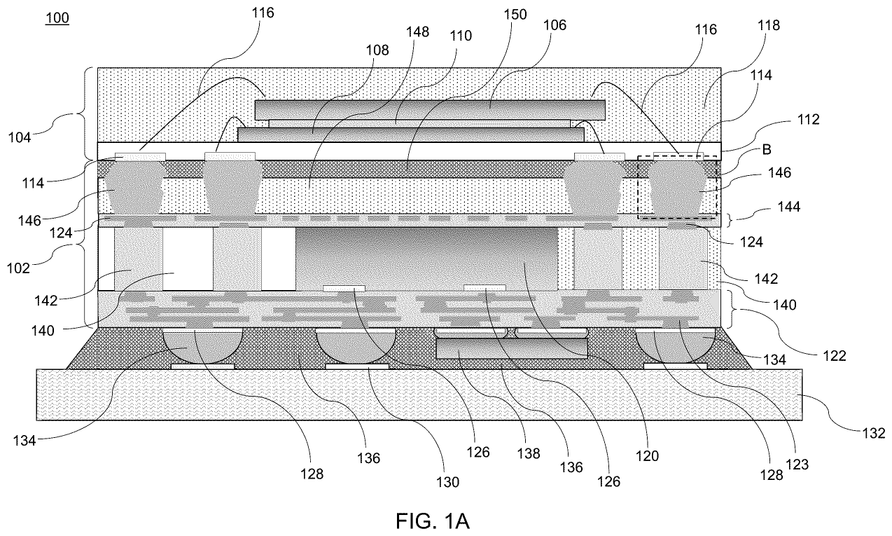

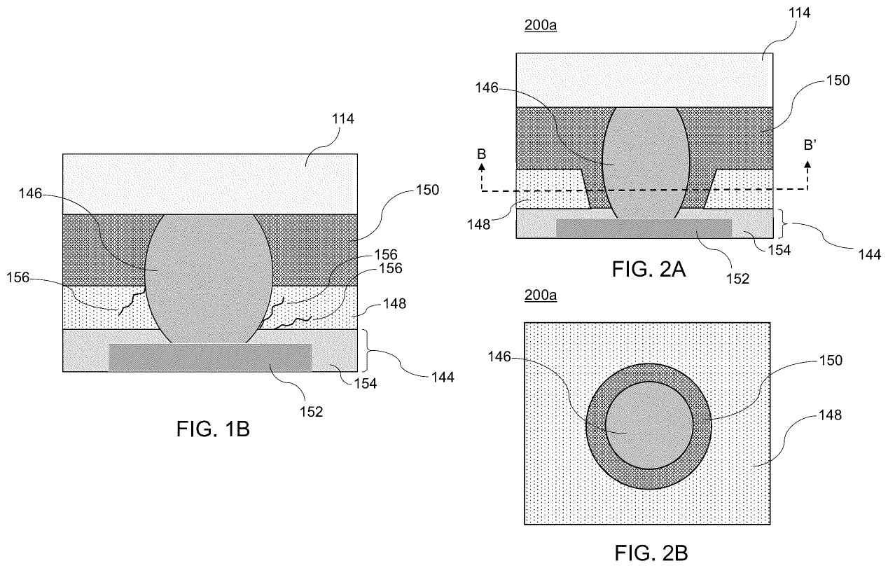

FIG. 1A is a vertical cross-sectional view of a related semiconductor device 100. In this related semiconductor device, the semiconductor device 100 may be configured as a package-on-package structure. In this regard, the semiconductor device 100 may include a second package 104 attached and electrically coupled to a first package 102. The second package 104 may include a first memory die 106 stacked on a second memory die 108. The first memory die 106 may be separated from the second memory die 108 by a spacer structure 110. The spacer structure 110 may be configured as a dummy die and may include a semiconductor material, an insulator material, a polymer material, etc. The first memory die 106 and the second memory die 108 may each be attached to the spacer structure 110 using an adhesive (e.g., a silicone-based adhesive). The first memory die 106, the second memory die 108, and the spacer structure 110 may form a memory die stack that may be attached to a first substrate 112.

The first substrate 112 may be a laminate substrate that may be configured to provide electrical connections between the second package 104 and the first package 102. In an example embodiment, the first substrate 112 may be configured as printed circuit board. In this regard, the first substrate 112 may include first bonding pads 114. As shown in FIG. 1A, the first memory die 106 and the second memory die 108 may each be wire bonded to the first bonding pads 114. In this regard, a plurality of wires 116 may electrically connect the first bonding pads 114 of the second package 104 to bonding pads (not shown) of the first memory die 106 and the second memory die 108. The second package 104 may further include a molding material (e.g., an epoxy material) formed as a first molding matrix 118 that may surround the first memory die 106 and the second memory die 108. The first molding matrix 118 may formed in contact with the first substrate 112 and may protect and mechanically strengthen to the second package 104.

The first package 102 may be configured as an integrated fanout (InFO) package including a semiconductor die 120 (e.g., an integrated circuit) attached to an interposer 122. The semiconductor die 120 may be configured as a system-on-chip die, a central processing unit (CPU) die, or any of various other types of integrated circuit dies. The interposer 122 may be a semiconductor interposer (e.g., a silicon interposer), a glass interposer, an organic (e.g., polymer-based) interposer, etc. The interposer 122 may include a redistribution layer including various electrical interconnect structures 123 that are formed in a fanout configuration. In this regard, the electrical interconnect structures 123 may have a first spacing at a top surface of the interposer 122 corresponding to a first pitch of electrical bonding pads (e.g., second bonding pads 126) of the semiconductor die 120.

The electrical interconnect structures 123 may further have a second (larger) spacing at a bottom surface of the interposer 122 corresponding to a second (larger) pitch of bonding pads (e.g., third bonding pads 128) on the bottom surface of the interposer 122. The larger pitch of the third bonding pads 128 may correspond to a spacing of bonding pads (e.g., fourth bonding pads 130) of a second substrate 132 (e.g., a printed circuit board) to which the first package 102 may be attached and electrically coupled. In this regard, a plurality of first solder material portions 134 may be provided, which may be reflowed to form an electrical and mechanical connections between the third bonding pads 128 of the interposer 122 and the fourth bonding pads 130 of the second substrate.

A first underfill material 136 may then be provided between the bottom surface of the interposer 122 and a top surface of the second substrate 132. The first underfill material 136 may surround and protect the first solder material portions 134, the third bonding pads 128, and the fourth bonding pads 130, and may provide structure stability to the composite structure including the interposer 122 and the second substrate 132. In certain embodiments, one or more surface mounted devices 138 may also be attached and electrically coupled to the interposer 122, as show in FIG. 1A. For example, the surface mounted device 138 may include one or more integrated passive devices that may include passive components such as resistors, capacitors, inductors, diodes, antennas, etc.

The first package 102 may further include a second molding matrix 140 having one or more through-molding-material vias 142 formed therein. The first package 102 may further include a redistribution layer 144 formed on a top surface of the second molding matrix 140. The redistribution layer 144 may include electrical interconnect structures 124 and may be electrically coupled to the through-molding-material vias 142. The first package 102 may further include second solder material portions 146 that may be electrically coupled to the redistribution layer 144. The second package 104 may be attached and electrically coupled to the first package 102 by aligning the first bonding pads 114 of the second package 104 with the second solder material portions 146. A reflow operation may then be performed to electrically and mechanically attached the first bonding pads 114 to the second solder material portions 146.

A third molding matrix 148 may be formed over the redistribution layer 144 and may provide mechanical stability to the first package 102 and to reduce or mitigate the formation of mechanical defects and distortions (e.g., warping). As shown, the third molding matrix 148 may be formed around the second solder material portions 146 and may be mechanically bonded to surfaces of the second solder material portions 146. A second underfill material 150 may then be formed between a bottom surface of the second package 104 and a top surface of the first package 102 (e.g., a top surface of the third molding matrix). As shown in FIG. 1A, the second underfill material 150 may surround and protect top portions of the second solder material portions 146 and the first bonding pads 114.

FIG. 1B is an enlarged vertical cross-sectional view of a portion B of the semiconductor device 100 of FIG. 1A. The second solder material portion 146 may form a mechanical and electrical connection between the first bonding pad 114 of the second package 104 and a fifth bonding pad 152 of the redistribution layer 144. The redistribution layer 144 may include a plurality of electrical interconnect structures 124 (e.g., see FIG. 1A) formed in a dielectric material 154 (e.g., a polymer material that may be a first film 154). The third molding matrix 148 (may be formed as a second film 148) and the second underfill material 150 may be formed such that a direct mechanical connection is formed at interfaces with the second solder material portion 146. As such, during thermal cycling, mechanical strains may develop at interfaces between the second solder material portion 146 and third molding matrix 148, and between the second solder material portion 146 the second underfill material 150, due to relative differences in the coefficients of thermal expansion of the solder material portion 146, and the second solder material portion 146. Mechanical defects, such as cracks 156, interface delamination (not shown), etc., may form when such mechanical strains exceed a threshold for crack initiation and/or a threshold for interface delamination.

In some embodiments, the third molding matrix 148 may include a reinforced epoxy material. For example, the third molding matrix 148 may include a reinforcing component (e.g., glass fiber) suspended in an epoxy material. In some embodiments, the reinforcing component may be present in a concentration greater than or equal to 50% by weight. In other embodiments, the fiber content may be greater than or equal to 50% by volume. In still further embodiments, the third molding matrix 148 may include other reinforcing components, such as polymer fibers, carbon fibers, etc. The third molding matrix 148 may have having a film modulus greater than 3 GPa, a fracture toughness greater than 0.5 MPa m½, and a film coefficient of thermal expansion (CTE) greater than 10 ppm/° C.

The second solder material portion 146 may have a Young's modulus that may be in a range from approximately 40 GPa to approximately 90 GPa and a CTE that is in a range from approximately 20 ppm/° C. to approximately 25 ppm/° C. The second underfill material may have a Young's modulus of approximately 2.6 GPa and CTE of approximately 55 ppm/° C. for temperatures below the glass transition temperature (113° C.) and may have a CTE of approximately 171 ppm/° C. for temperatures above the glass transition temperatures. In some embodiments, a manufacturing thermal cycle may be in a range from approximately −65° C. to approximately 150° C. As such, given the differences in mechanical and thermal expansion properties, thermally induced stresses/strains may be significant and may lead to mechanical degradation (e.g., cracking, delamination, etc.).

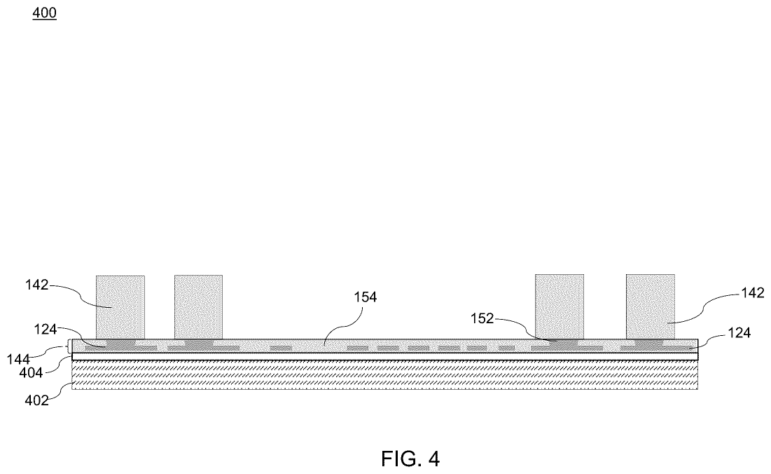

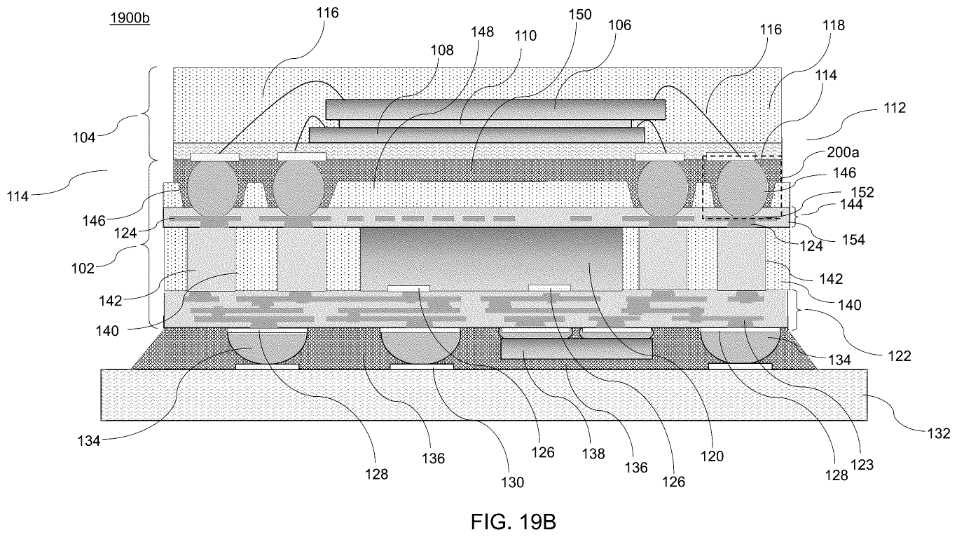

FIG. 2A is a vertical cross-sectional view of a bonding structure 200a for a semiconductor device (1900a, 1900b) (e.g., see FIGS. 19A and 19B) that may have improved mechanical properties relative to the semiconductor device 100 of FIG. 1A, according to various embodiments. As described in greater detail with reference to FIGS. 4 to 18, below, the semiconductor device (1900a, 1900b) may include a similar components to the related semiconductor device 100 of FIG. 1A, including a second package 104 electrically and mechanically coupled to a first package 102. The coupling may be modified, however, to reduce the occurrence of thermally induced stresses/strains. As such, a corresponding thermally induced mechanical degradation may be reduced or mitigated.

As with the related semiconductor device 100 of FIGS. 1A and 1B, the bonding structure 200a of FIGS. 2A and 2B may include a second solder material portion 146 that may electrically and mechanically couple a first bonding pad 114 of the second package 104 to a fifth bonding pad 152 of the first package 102. Similarly, the first package 102 may include a third molding matrix 148 that may provide mechanical strength to the first package 102 and may reduce the incidence of mechanical distortions (e.g., warping). The first package 102 may further include a second underfill material 150 formed in a space between a bottom surface of the second package 104 (e.g., below the first bonding pad 114) and a top surface of the first package 102 (e.g., above a top surface of the redistribution layer 144). In contrast to the related semiconductor device 100, however, the third molding matrix 148 of the semiconductor device (1900a, 1900b) (e.g., see FIGS. 2A, 2B, 19A, and 19B) may include an aperture such that the second solder material portion 146 does not contact the third molding matrix 148. As such, the bonding structure 200a may include a stacked film structure including a first film 154 and a second film 148. The first film 154 may be formed as the dielectric material 154 of the redistribution layer 144, and the second film 148 may be formed as the third molding matrix 148.

FIG. 2B is a horizontal cross-sectional view of the bonding structure 200a of the semiconductor device (1900a, 1900b) of FIGS. 2A, 19A, and 19B, according to various embodiments. The horizontal plane defining the cross-sectional view of FIG. 2B is indicated by the cross-section B-B′ in FIG. 2A. As shown, the second film 148 may include an aperture surrounding the second solder material portion 146 such that the second film 148 does not contact the second solder material portion 146. Rather, the second underfill material 150 may be formed in a space between the second film 148 and the second solder material portion 146. In the example embodiments of FIGS. 2A and 2B the aperture in the second film 148 is illustrated as a circular aperture. In other embodiments, however, the aperture may have various other shapes, such as an ellipse, a square, a rectangle, a regular polygon, etc.

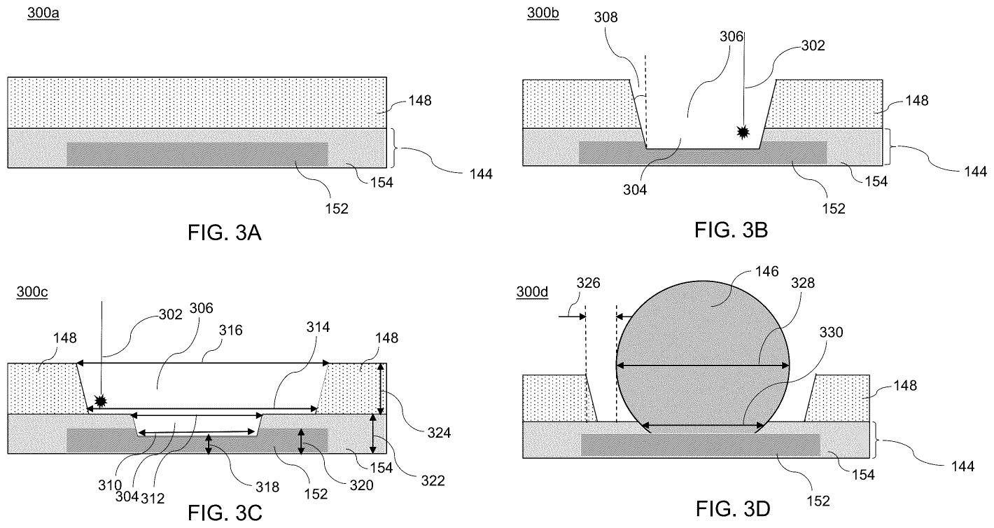

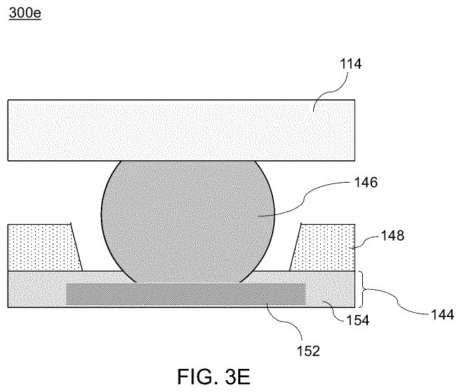

As described in greater detail with reference to FIGS. 3B and 3C, a similar aperture may be formed in the first film 154 of the redistribution layer 144. As such, as shown in FIG. 2A, the second solder material portion 146 may contact the fifth bonding pad 152, the first film 154, and the second underfill material 150, but may not be in contact with the second film 148. By independently varying the size, shape, and thickness of each of the apertures (i.e., the aperture in the second film 148 and the aperture in the first film 154) the mechanical properties may accordingly be varied. In some embodiments, the thermally induced mechanical stresses/strains may be reduced by up to 30% relative to the corresponding structure of the related semiconductor device 100 shown in FIG. 1B. Thus, various thermally induced mechanical defects/degradation may be reduced or eliminated by optimizing various geometric parameters of the bonding structure of FIGS. 2A and 2B.

FIGS. 3A to 3E are vertical cross-sectional views of intermediate structures 300a to 300e, respectively, that may be used in the formation of the bonding structure 200a of FIGS. 2A and 2B, according to various embodiments. As shown in FIG. 3A, the second film 148 may be formed over a top surface of the redistribution layer 144 in intermediate structure 300a. As described above with reference to FIG. 1B, the redistribution layer 144 may have various electrical interconnect structures 124 (e.g., see FIG. 1A) formed in a first film 154. The electrical interconnect structures 124 may further include a plurality of fifth bonding pads 152 that may be initially covered by the first film 154 (e.g., see FIG. 3A).

As shown in FIG. 3B, a portion of the second film 148 and the first film 154 may be removed to thereby expose a top surface of the fifth bonding pad 152 in intermediate structure 300b. In one embodiment, the portion of the second film 148 and the first film 154 may be removed by performing a laser drilling operation in which laser radiation 302 may be focused on a localized region of the second film 148 and the first film 154. The laser radiation 302 may cause melting and/or vaporization of the portion of the second film 148 and the first film 154. In this way, a first aperture 304 (i.e., an aperture in the first film 154) and a second aperture 306 (i.e., an aperture in the second film 148) may be formed. In other embodiments, the first aperture 304 and the second aperture 306 may be formed by performing an anisotropic etching process using a patterned mask (e.g., a patterned photoresist, not shown).

As shown in FIG. 3B, the first aperture 304 aperture may expose a portion of the fifth bonding pad 152, and the second aperture 306 may be formed over the first aperture 304 such that the first aperture 304 is located entirely below an area of the second aperture 306 in intermediate structure 300c. The first aperture 304 and the second aperture 306 may be tapered so that each of the first aperture 304 and the second aperture 306 have walls that subtend a taper angle 308 relative a vertical direction. The taper angle 308 may take on various values depending on how the laser drilling operation is performed. For example, the taper angle 308 may be in a range from approximately 0 degrees to 50 degrees. The laser radiation 302 may have a power that is in range from approximately 0.5 W to approximately 1.0 W. Various intensities (i.e., power per unit area) of the laser radiation 302 may be generated by varying the spot size of the laser radiation 302. For example, a diameter of the spot size of the laser radiation 302 may be chosen to have a value within a range from approximately 100 microns to approximately 240 microns. Apertures of various sizes may be formed by moving the laser radiation 302 relative to the second film 148 and the first film 154, as described in greater detail below.

As shown in FIG. 3C, a second laser drilling process may be performed to increase a width of the second aperture 306. The laser radiation 302 used in the second laser drilling operation may have a lower intensity than was used in the first laser drilling operation. In this way, the second laser drilling process may have a sufficient intensity to remove an additional portion of the second film 148 without removing an additional portion from the first film 154. The first aperture 304 may have a first width 310 at a bottom portion of the first aperture 304 and a second width 312 at a top portion of the first aperture 304. In some embodiments, the first width 310 and the second width 312 may have a value that is approximately equal in embodiments in which the taper angle 308 is approximately 0 degrees (i.e., vertical aperture walls). In other embodiments, the second width 312 may be larger than the first width 310 and may be a function of the taper angle 308. The first width 310 and the second width 312 may have values that are in a range from approximately 100 microns to approximately 300 microns.

Similarly, the second aperture 306 may have a third width 314 at a bottom portion of the second aperture 306 and a fourth width 316 at a top portion of the second aperture 306. In some embodiments, the third width 314 and the fourth width 316 may be approximately equal (e.g., in embodiments in which the taper angle 308 is approximately 0 degrees), as was the case with the first aperture 304. In other embodiments, the fourth width 316 may be larger than the third width 314 and may be a function of the taper angle 308. The third width 314 and the fourth width 316 may have values that are in a range from approximately 110 microns to approximately 500 microns.

As shown in FIG. 3C, the first width 310, the second width 312, the third width 314, and the fourth width 316 may be less than or equal to a width of the fifth bonding pad 152. Further, as shown in FIG. 3C, a thickness of the fifth bonding pad 152 may vary across a width of the fifth bonding pad 152. For example, the first laser drilling operation may remove a small portion of the top surface of the fifth bonding pad 152. As such, the fifth bonding pad 152 may have a first thickness 318, under the first aperture 304, that may be smaller than a second thickness 320 adjacent to an area of the first aperture 304. The first thickness 318 and the second thickness 320 may have values in a range from approximately 2 microns to approximately 20 microns. The first film 154 may have a third thickness 322 that may have a value in a range from 5 microns to 40 microns, and the second film 148 may have a fourth thickness 324 that is in a range from approximately 5 microns to 500 microns.

FIG. 3D is a vertical cross-sectional view of a further intermediate structure 300d that may be used in the formation of a bonding structure (e.g., the bonding structure of FIG. 2A), according to various embodiments. The intermediate structure 300d may be formed from the intermediate structure 300c of FIG. 3C by forming the second solder material portion 146 over the fifth bonding pad 152 such that the second solder material portion 146 is in contact with the fifth bonding pad 152 and with the first film 154. As shown, a size of the second solder material portion 146 may be chosen such that the second solder material portion 146 fits within the first aperture 304 and within the second aperture 306 (e.g., see FIGS. 3B to 3D) without touching the second film 148.

As shown in FIG. 3D, the relative sizes of the first aperture 304 and the second aperture 306 may be chosen such that a pre-determined separation 326 may be formed between the second solder material portion 146 and an edge of the second film 148 (i.e., an edge of the second aperture 306). In an example embodiment, the pre-determined separation 326 may have a value that may be greater than or equal to 5 microns. In this regard, the second solder material portion 146 may have a fifth width 328 that is less than a size of the second aperture 306 such that the second solder material portion 146 does not contact the second film 148. The second solder material portion 146 may further have a sixth width 330 that is similar to a size of the first aperture 304 such that the second solder material portion 146 is in contact with the first film 154.

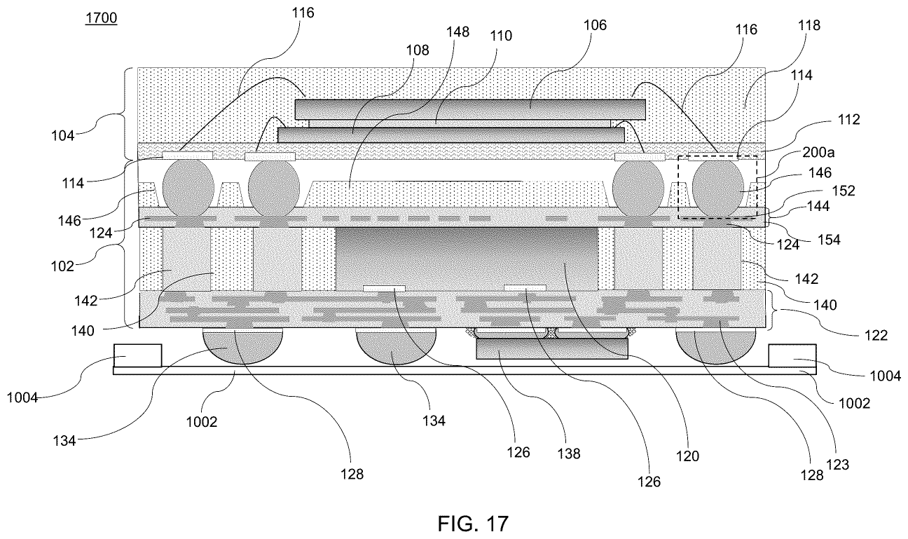

FIG. 3E is a vertical cross-sectional view of a further intermediate structure 300e that may be used in the formation of a bonding structure (e.g., the bonding structure of FIG. 2A), according to various embodiments. The intermediate structure 300e may be formed from the intermediate structure 300d of FIG. 3D by bonding the first bonding pad 114 of the second package 104 (e.g., see FIGS. 1A to 2A) to the second solder material portion 146. In this regard, the second package 104 may be aligned relative to the first package 102 such that the first bonding pads 114 are aligned with the second solder material portions 146 (e.g., see FIG. 17 and related description, below). A reflow operation may then be performed to reflow the solder material portions 146 such that a metallurgical bond may be formed between the second solder material portions 146 and the first bonding pads 114, and between the second solder material portions 146 and the fifth bonding pads 152, as shown in FIG. 3E. The second underfill material 150 may then be formed between a bottom surface of the second package 104 (e.g., between a bottom surface of the first bonding pads 114) and a top surface of the first package 102 as shown, for example, in FIGS. 2A, 19A, and 19B. Methods of fabricating the semiconductor device (1900a, 1900b) (i.e., a package-on-package structure including the improved bonding structures of FIG. 2A) are described in greater detail with reference to FIGS. 4 to 19B, below.

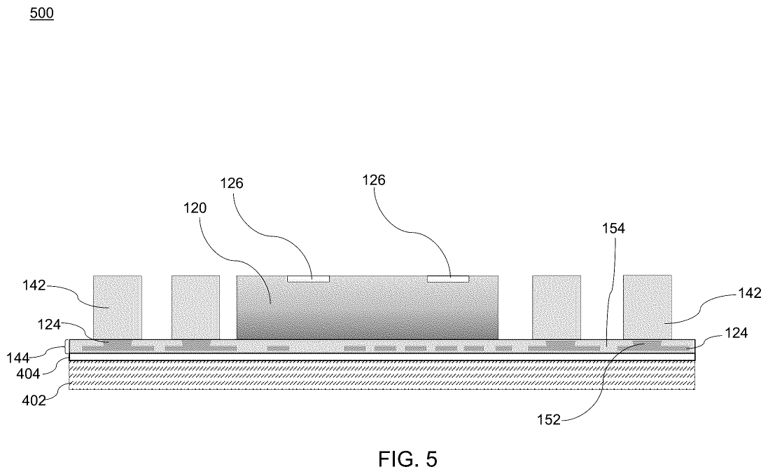

FIG. 4 is a vertical cross-sectional view of an intermediate structure 400 that may be used in the formation of a semiconductor device (1900a, 1900b) (e.g., see FIGS. 19A, and 19B), according to various embodiments. The intermediate structure 400 may include a carrier substrate 402 with a redistribution layer 144 (having electrical interconnect structures 124 formed therein) formed over the carrier substrate 402. The carrier substrate 402 may further include an adhesive layer 404 located on a surface of the carrier substrate 402 in between the carrier substrate 402 and the redistribution layer 144. In some embodiments, the carrier substrate 402 may include, for example, silicon-based materials, such as glass, ceramics or silicon oxide, or other materials, such as aluminum oxide, combinations of any of these materials, etc. The carrier substrate 402 may be configured to have a planar surface to accommodate attachment of one or more semiconductor dies such as the semiconductor die 120 shown in FIGS. 1A and 5.

The adhesive layer 404 may be placed on the carrier substrate 402 to removably attach overlying structures (e.g., the redistribution layer 144) to the carrier substrate 402. In an example embodiment, the adhesive layer 404 may include an ultraviolet glue, which may be configured to lose its adhesive properties when exposed to ultraviolet light. In further embodiments, other types of adhesives, such as pressure sensitive adhesives, radiation curable adhesives, light to heat conversion release coating (LTHC), epoxies, combinations of these, etc., may also be used. The adhesive layer 404 may be placed onto the carrier substrate 402 in a semi-liquid or gel form, which may be readily deformable under pressure.

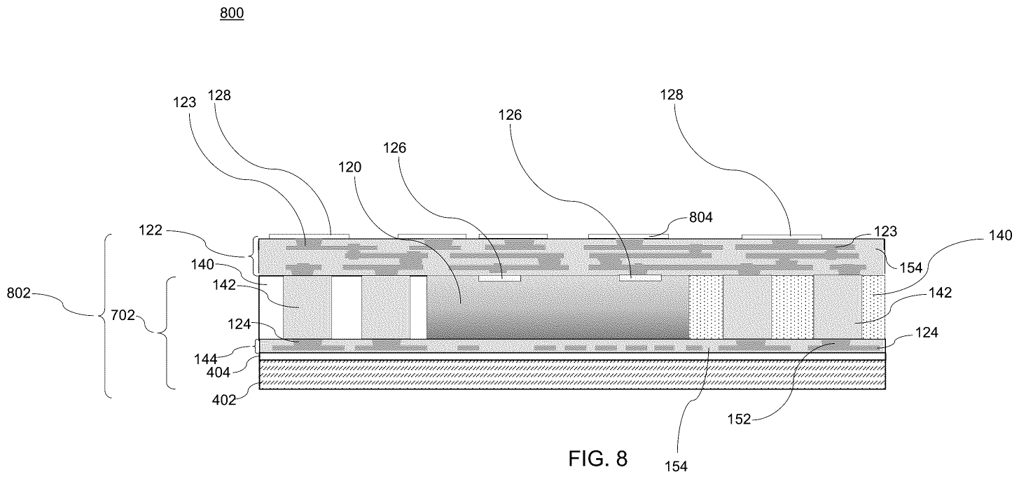

In some embodiments, a package structure (e.g., the first package 102 as shown in FIGS. 1A, 19A, and 19B) may be formed on the adhesive layer 404. In some embodiments, the first package 102 may be configured as an InFO package, although other types of packages may be used in other embodiments. In various disclosed embodiments, the first package 102 may include a reconstructed wafer 802, as described in greater detail with reference to FIG. 8, below.

The redistribution layer 144 may include at least one insulating layer (not shown). The insulating layer may be placed over the redistribution layer 144 and may be utilized to provide protection to, for example, the semiconductor die 120 once the semiconductor die 120 has been attached. In an embodiment, the insulating layer may include polybenzoxazole (P130), although any suitable material, such as polyimide or a polyimide derivative, may alternatively be utilized. The insulating layer may be placed using, for example, a spin-coating process to deposit a film having a thickness in a range from about 2 microns and about 15 microns, such as about 5 microns, although any suitable method and thickness may alternatively be used. In some embodiments, the redistribution layer 144 may further include a circuit layer for electrically connecting the semiconductor die 120 once the semiconductor die 120 has been attached.

A plurality of through-molding-material vias 142 may then be formed on the carrier substrate 402. The through-molding-material vias 142 may be configured to surround at least one device area where the semiconductor die 120 may be disposed. The through-molding-material vias 142 may be formed on and electrically connected to the redistribution layer 144 located on the carrier substrate 402. In other embodiments, the through-molding-material vias 142 may be pre-formed as separate structures, which may then be placed on the carrier redistribution layer 144.

The through-molding-material vias 142 may be formed on the carrier substrate 402 as follows. A seed layer may be formed over the redistribution layer 144. The seed layer may be a thin layer of a conductive material that aids in the formation of a thicker layer during subsequent processing steps. For example, the seed layer may include a layer of titanium having a layer of copper formed thereon. The titanium may have a thickness of approximately 1,000 angstroms and the copper may have a thickness of approximately 5,000 angstroms. The seed layer may be deposited using various processes such as sputtering, evaporation, or plasma-enhanced chemical vapor deposition (PECVD), etc., depending upon the materials chosen for the seed layer.

A photoresist (not shown) may then be formed over the seed layer using, for example, a spin coating technique. The photoresist may then be patterned by exposing the photoresist to a patterned energy source (e.g., a patterned light source), thereby inducing a physical change in those portions of the photoresist exposed to the patterned light source. A developer may then be applied to the exposed photoresist to selectively remove either the exposed portion of the photoresist or the unexposed portion of the photoresist, depending upon the desired pattern. The pattern formed into the photoresist may then be used to generate the through-molding-material vias 142. The through-molding-material vias 142 may be formed in locations around an area in which the semiconductor die 120 may be subsequently attached.

The through-molding-material vias 142 may then be formed by deposition of a conducting material in regions that are not masked by photoresist. Conductive materials that may be used to form the through-molding-material vias 142 may include copper, tungsten, or other conductive metals. Such materials may be deposed, for example, by electroplating, electroless plating, etc. In an example embodiment, an electroplating process may be used for plating the exposed conductive areas of the seed layer within openings of the photoresist. Once the through-molding-material vias are formed using the photoresist and the seed layer, the photoresist may be removed using a suitable removal process. For example, a plasma ashing process may be used to remove the photoresist, whereby the temperature of the photoresist may be increased until the photoresist experiences a thermal decomposition that allows the photoresist to be removed. In other embodiments, other suitable process, such as a wet strip, may be utilized. The removal of the photoresist may expose the underlying portions of the seed layer.

Exposed portions of the seed layer (e.g., those portions that are not covered by the through-molding-material vias 142) may be removed by, for example, a wet or dry etching process. For example, in a dry etching process reactants may be directed towards the seed layer, using the through-molding-material vias 142 as masks. Alternatively, etchants may be sprayed or otherwise put into contact with the seed layer to remove the exposed portions of the seed layer. After the exposed portion of the seed layer has been removed (e.g., etched away), a portion of the redistribution layer 144 may be exposed between the through-molding-material vias 142, thus completing the process of forming the through-molding-material vias 142.

FIG. 5 is a vertical cross-sectional view of a further intermediate structure 500 that may be used in the formation of the semiconductor device (1900a, 1900b), according to various embodiments. The intermediate structure 500 may be formed from the intermediate structure 400 of FIG. 4 by attaching the semiconductor die 120 to a top surface of the redistribution layer 144. As described above, the semiconductor die 120 may include various electrical connections, such as second bonding pads 126. The second bonding pads 126 may be electrically connected to other circuit components in later processing operations. For example, the second bonding pads 126 may be connected to the interposer 122 (e.g., see FIGS. 1A and 8). As shown, the semiconductor die 120 may be placed in an area between the through-molding-material vias 142 such that the semiconductor die 120 is effectively surrounded by the through-molding-material vias 142.

The semiconductor die 120 may be attached to the redistribution layer 144 using an adhesive material, although any suitable method of attachment may alternatively be utilized. The intermediate structure 500 may correspond to a single repeat unit in two-dimensional array of similar structure that may be formed on the carrier substrate 402. As such, a plurality of package-on-package structures may be formed concurrently for batch production. To simplify the following description, processing operations are described with reference to a single package-on-package structure.

In some embodiments, the semiconductor die 120 may be a logic device die including logic circuits formed therein. In other embodiments, the semiconductor die 120 may be configured for mobile applications and may include a power management integrated circuit (PMIC) die and a transceiver (TRX) die. One or more additional semiconductor dies (not shown) may be placed over the redistribution layer 144 adjacent one another in other embodiments. The semiconductor die 120 may include a plurality of integrated circuits formed on a device substrate (not shown). The integrated circuits may be electrically coupled to the second bonding pads 126, as described above.

The device substrate on which the integrated circuits of the semiconductor die 120 are formed may include bulk silicon, doped or undoped silicon, an active layer of a silicon-on-insulator (SOI) substrate, or another doped or undoped semiconductor substrate. An SOI substrate, for example, may include a layer of a semiconductor material such as silicon, germanium, silicon germanium, SOI, silicon germanium on insulator (SGOI), or combinations thereof. Other substrates that may be used may include multi-layered substrates, gradient substrates, or hybrid orientation substrates. The integrated circuits may include a variety of active devices and passive devices such as capacitors, resistors, inductors, etc., that may be used to generate desired structural and functional requirements of the design for the semiconductor 120. The integrated circuits may be formed using any suitable methods either within or on the substrate.

In some embodiments, the top ends of the through-molding-material vias 142 may be level with the top surfaces of the second bonding pads 126. In other embodiments, the top ends of the through-molding-material vias 142 may be higher than the top surfaces of the second bonding pads 126. Alternatively, the top ends of the through-molding-material vias 142 may be lower than the top surfaces of the second bonding pads 126 but higher than the bottom surfaces of the second bonding pads 126.

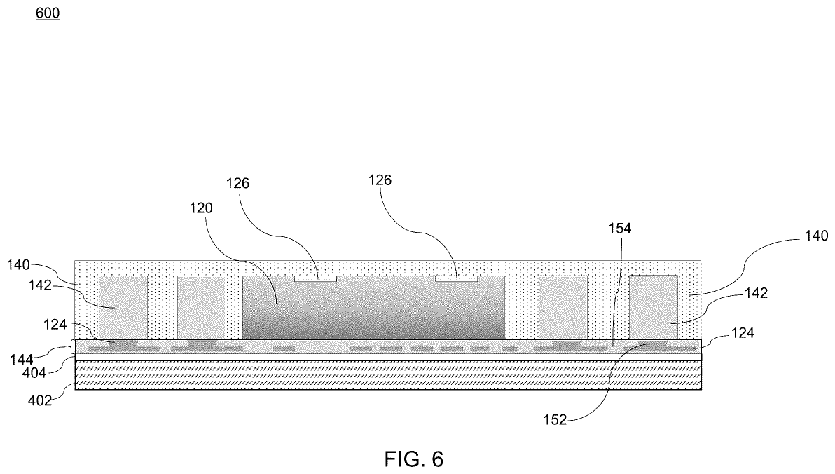

FIG. 6 is a vertical cross-sectional view of a further intermediate structure 600 that may be used in the formation of the semiconductor device (1900a, 1900b), according to various embodiments. The intermediate structure 600 may be formed from the intermediate structure 500 of FIG. 5 by forming a molding material 140 over the semiconductor die 120, the through-molding-material vias 142, and the redistribution layer 144 to thereby encapsulate the semiconductor die 120 and the through-molding-material vias 142.

In some embodiments, the molding material 140 may fill gaps between the semiconductor die 120 and the through-molding-material vias 142 and may be in contact with the redistribution layer 144. The molding material 140 may include a molding compound resin such as polyimide, PPS, PEEK, PES, a heat resistant crystal resin, combinations of these, etc. The encapsulation of the semiconductor die 120 and the through-molding-material vias 142 may be performed in a molding device (not shown in FIG. 6). The molding material 140 may be placed within a molding cavity of the molding device, or else may be injected into the molding cavity through an injection port.

Once the molding material 140 has been placed into the molding cavity such that the molding material 140 encapsulates the carrier substrate 402, the semiconductor die 120, and the through-molding-material vias 142, the molding material 140 may be cured to harden the molding material 140. Additionally, initiators and/or catalysts may be included within the molding material 140 to better control the curing process. In some embodiments, a top surface of the molding material 140 may be higher than the top ends of the through-molding-material vias 142 and the top surface of the semiconductor die 120, as shown in FIG. 6.

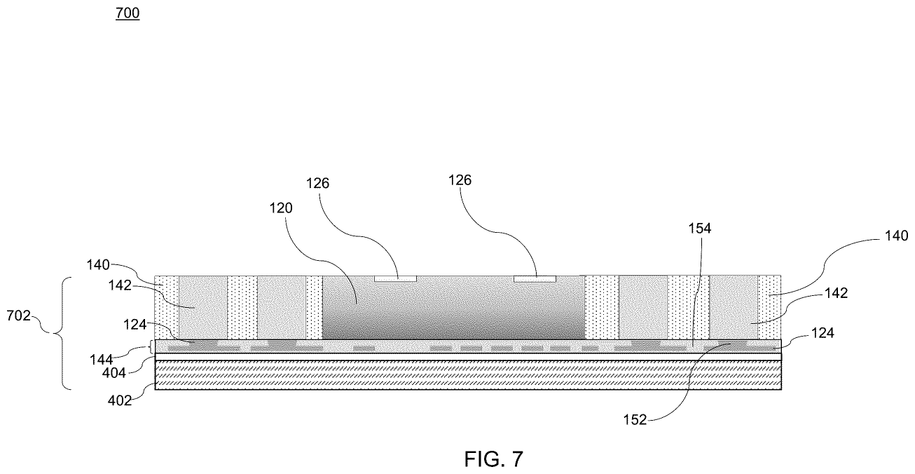

FIG. 7 is a vertical cross-sectional view of a further intermediate structure 700 that may be used in the formation of the semiconductor device (1900a, 1900b), according to various embodiments. The intermediate structure 700 may be formed from the intermediate structure 600 of FIG. 6 by performing a thinning process to remove a top portion of the molding material 140 to thereby form the second molding matrix 140. The thinning process may be performed on the molding material 140 to reveal the top ends of the through-molding-material vias 142 and the top surfaces of the second bonding pads 126.

The thinning process may include a mechanical grinding or chemical mechanical polishing (CMP)140 process whereby chemical etchants and abrasives are utilized to react and grind away a portion of the molding material 140 to expose top surfaces of the through-molding-material vias 142 the second bonding pads 126. The resulting structure is shown in FIG. 7. The thinning process may also remove top portions of the through-molding-material vias 142 and/or top portions of the second bonding pads 126 such that the top ends of the through-molding-material vias 142, top surfaces of the second bonding pads 126, and a top surface of the second molding matrix 140 are level with one another, as shown in FIG. 7.

Although the above-described CMP process may be used to perform the thinning process, various other removal processes may be used in other embodiments. For example, one or more chemical etching processes may be performed to thin the second molding matrix 140, the semiconductor die 120, and the through-molding-material vias 142. All such alternative thinning processes are within the contemplated scope of this disclosure.

The structure of FIG. 7, including the semiconductor die 120, the through-molding-material vias 142, and the second molding matrix 140 may be referred to as an encapsulated semiconductor device 702. Further, the encapsulated semiconductor device 702 may be formed as one of a plurality of similar encapsulated semiconductor devices 702 on a wafer. Accordingly, in each encapsulated semiconductor device 702, the semiconductor die 120 may be disposed in a die area, the through-molding-material vias 142 may extend through the encapsulated semiconductor device 702 outside of the die area, and the second molding matrix 140 may encapsulate the semiconductor die 120 and the through-molding-material vias 142. In other words, the second molding matrix 140 may encapsulate the semiconductor die 120 therein, and the through-molding-material vias 142 extend through the second molding matrix 140.

FIG. 8 is a vertical cross-sectional view of a further intermediate structure 800 that may be used in the formation of the semiconductor device (1900a, 1900b), according to various embodiments. The intermediate structure 800 may be formed from the intermediate structure 700 of FIG. 7 by forming the interposer 122 (i.e., a further redistribution layer similar to the redistribution layer 144) over a first side of the encapsulated semiconductor device 702. The interposer 122 may be electrically connected to the semiconductor die 120 and the through-molding-material vias 142. In some embodiments, the interposer 122 may be formed over the encapsulated semiconductor device 702 (including the second molding matrix 140 and the semiconductor die 120) to connect to the second bonding pads 126 of the semiconductor die 120 and the through-molding-material vias 142.

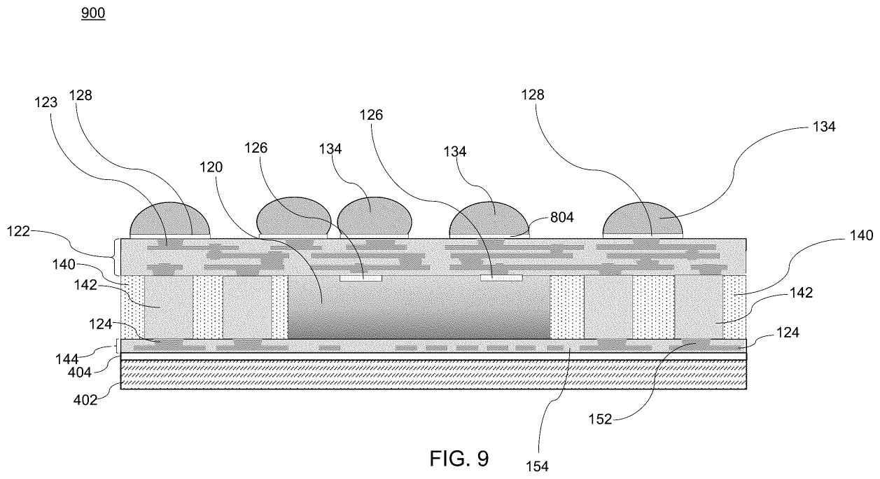

The interposer 122 may be formed by, for example, depositing conductive layers, patterning the conductive layers to form electrical interconnect structures 124, partially covering the electrical interconnect structures 124 and filling the gaps between the electrical interconnect structures 124 with dielectric layers 154, etc. The material of the electrical interconnect structures 124 may include a metal or a metal alloy including aluminum, copper, tungsten, and/or alloys thereof. The dielectric layers 154 may be formed of dielectric materials such as oxides, nitrides, carbides, carbon nitrides, combinations thereof, and/or multi-layers thereof. The electrical interconnect structures 124 may be formed in the dielectric layers 154 and may be electrically connected to the semiconductor die 120 and the through-molding-material vias 142. The electrical interconnect structures 124 may further include an under-bump metallurgy (UBM) layer 804, as described in greater detail with reference to FIG. 9, below.

As shown in FIG. 8, the interposer 122 and the redistribution layer 144 and the interposer 122 may be disposed on opposite sides of the encapsulated semiconductor device 702. The structure including the interposer 122, the encapsulated semiconductor device 702, and the redistribution layer 144, may be referred to as a reconstructed wafer 802.

FIG. 9 is a vertical cross-sectional view of a further intermediate structure 900 that may be used in the formation of the semiconductor device (1900a, 1900b), according to various embodiments. The intermediate structure 900 may be formed from the intermediate structure 800 by forming a plurality of conductive bumps (i.e., first solder material portions 134) on the electrical interconnect structures 124. In some embodiments, the UBM layer 804 may be formed on the electrical interconnect structures 124 by sputtering, evaporation, or electroless plating, etc., and the first solder material portions 134 may be disposed on the UBM layer 804. The formation of the first solder material portions 134 may include placing solder balls on the UBM layer 804 (or on the electrical interconnect structures 124), and then reflowing the solder balls. In alternative embodiments, the formation of the first solder material portions 134 may include performing a plating process to form solder regions on the UBM layer 804 (or on the electrical interconnect structures 124), followed by reflowing the solder regions.

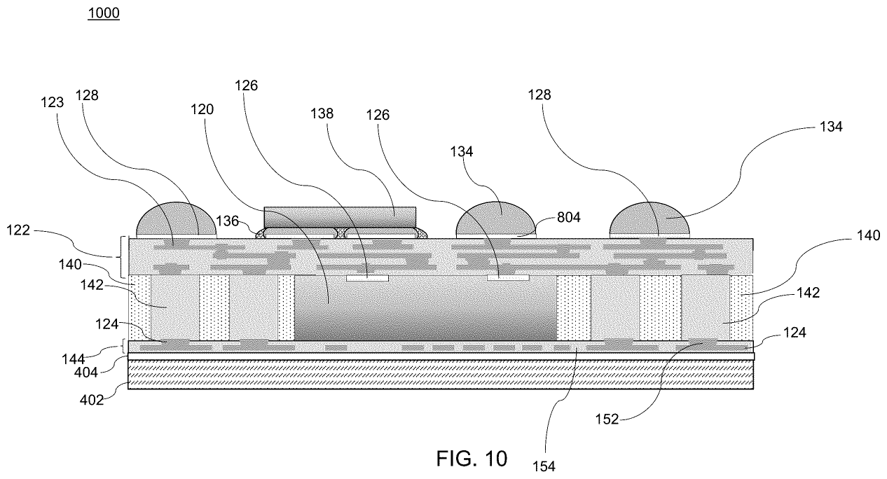

FIG. 10 is a vertical cross-sectional view of a further intermediate structure 1000 that may be used in the formation of the semiconductor device (1900a, 1900b), according to various embodiments. The intermediate structure 1000 may be formed from the intermediate structure 900 by attaching and electrically coupling an integrated passive device (IPD) 138 to the electrical interconnect structures 124. The IPD 138 may be fabricated using standard wafer fabrication technologies such as thin film and photolithography processing, and may be mounted on the first solder material portions 134 through, for example, flip-chip bonding or wire bonding, etc. The IPD 138 may include various passive electrical circuit elements such as resistors, capacitors, inductors, diodes, etc. Other embodiments may omit the IPD 138 or may include one or more additional IPDs (not shown). As shown, a first underfill material 136 may be formed between a surface of the interposer 122 and the IPD 1002.

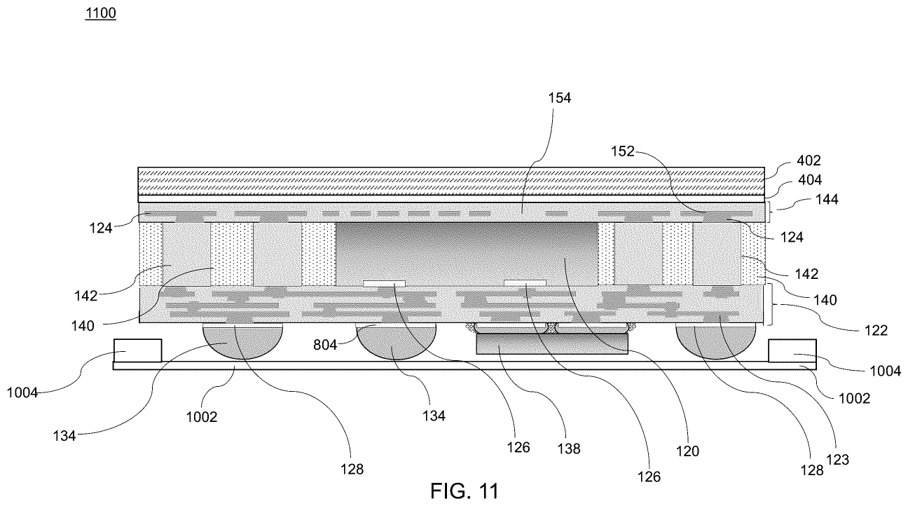

FIG. 11 is a vertical cross-sectional view of a further intermediate structure 1100 that may be used in the formation of the semiconductor device (1900a, 1900b), according to various embodiments. The intermediate structure 1100 may be formed by inverting the intermediate structure 1000 of FIG. 10 and disposing the intermediate structure 1100 on a tape carrier 1002. In this regard, the first solder material portions 134 may be attached to the tape carrier 1002. The tape carrier 1002 may further include a frame structure 1004, which may be a metal ring intended to provide support and stability to the intermediate structure 1100 during the subsequent processing operations. In some embodiments, the tape carrier 1002 may be made of a flexible polymer material. In one embodiment, a Young's modulus of the tape carrier 1002 may be smaller than 10 MPa, and a glass transition temperature (Tg) of the tape carrier 1002 may be less than room temperature. As such, when the tape carrier 1002 is used at or above the room temperature, the tape carrier 1002 may be in a rubbery state. Accordingly, in instances in which the first solder material portions 134 are attached to the tape carrier 1002, the tape carrier 1002 may deform slightly (not shown) to partially conform to a shape of the first solder material portions 134.

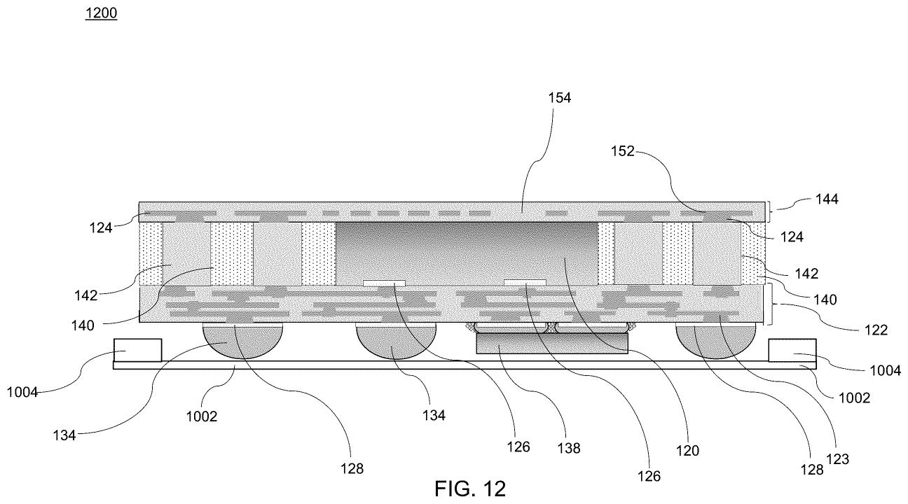

FIG. 12 is a vertical cross-sectional view of a further intermediate structure 1200 that may be used in the formation of the semiconductor device (1900a, 1900b), according to various embodiments. The intermediate structure 1200 may be formed from the intermediate structure 1100 by removing the carrier substrate 402. In this regard, the carrier substrate 402 may be de-bonded from the intermediate structure 1100 by using, for example, a thermal process to alter the adhesive properties of the adhesive layer 404 (e.g., see FIG. 11). For example, an energy source such as an ultraviolet (UV) laser, a carbon dioxide (CO2) laser, or an infrared (IR) laser, may be used to irradiate and heat the adhesive layer 404 until the adhesive layer 404 loses adhesion. Once performed, the carrier substrate 402 and the adhesive layer 404 may be physically separated and removed from the intermediate structure 1100 to form the intermediate structure 1200 shown in FIG. 12.

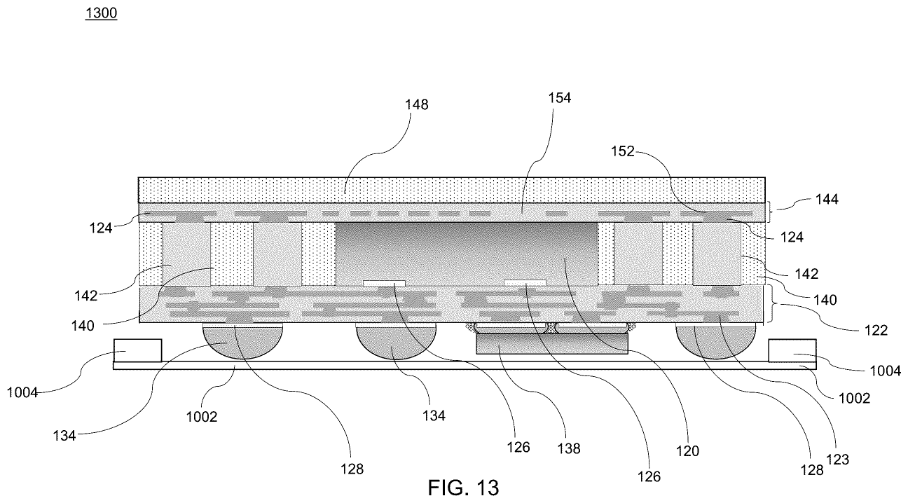

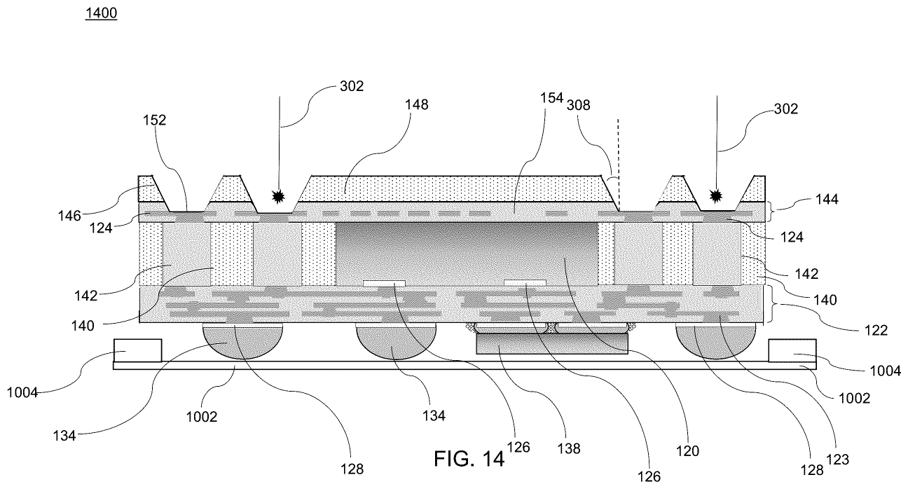

FIGS. 13 to 18 are vertical cross-sectional views of intermediate structures 1300 to 1700, respectively, that may be used in the formation of the semiconductor device (1900a, 1900b), according to various embodiments. Processes described with reference to FIGS. 13 to 17 directly correspond to the processes described with reference to FIGS. 3A to 3E, above. In this regard, the intermediate structure 1300 may be formed from the intermediate structure 1200 of FIG. 12 by formation of the second film 148 over the redistribution layer 144 of the intermediate structure 1200. The intermediate structure 1400 of FIG. 14 may be formed from the intermediate structure 1300 by performing a laser drilling operation to remove a portion of the second film 148 and the first film 154 to thereby expose a top surface of the fifth bonding pads 152, as described above with reference to FIG. 3B. In this way, a first aperture 304 in the first film 154 and a second aperture 306 in the second film 148 may be generated (e.g., see FIG. 3B and related description, above).

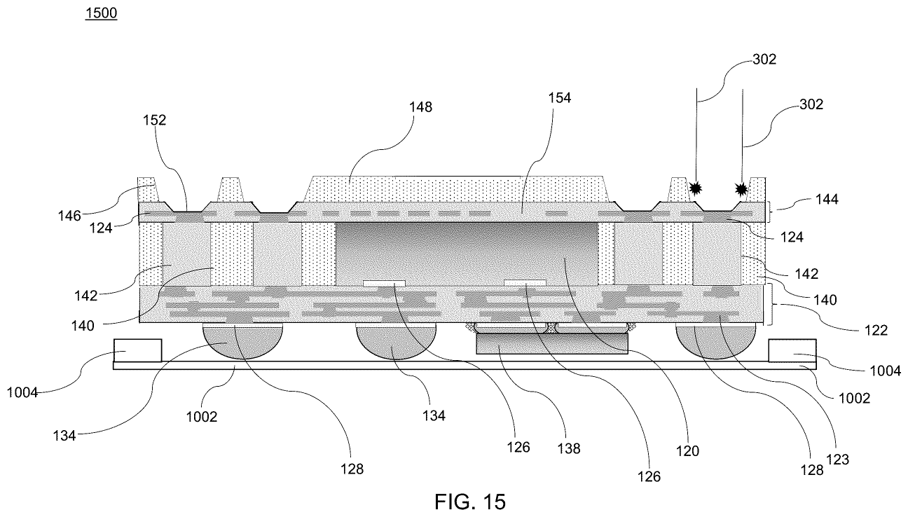

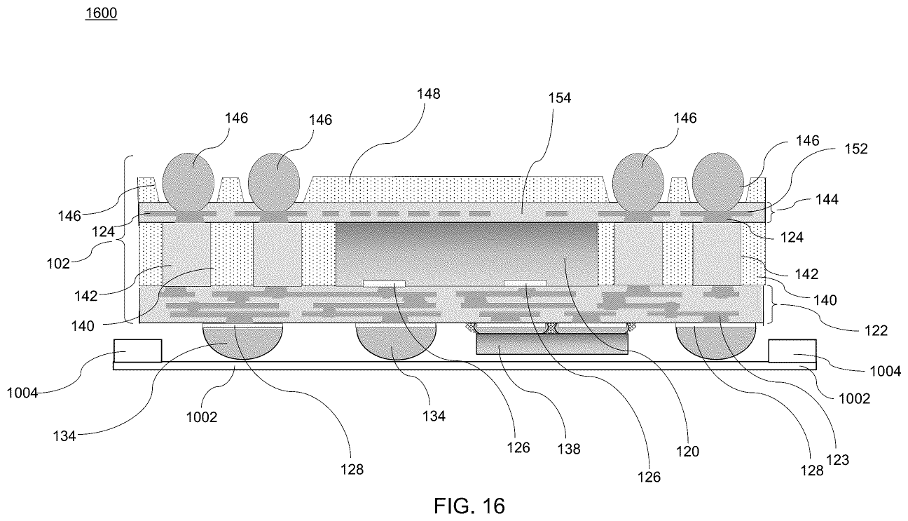

The intermediate structure 1500 of FIG. 15 may formed from the intermediate structure 1400 of FIG. 14 by performing a second laser drilling operation (i.e., introducing laser radiation 302) to increase a width of the second aperture 306 in the second film 148 (e.g., see FIG. 3C and related description, above). The intermediate structure 1600 of FIG. 16 may formed from the intermediate structure 1500 of FIG. 15 by forming the second solder material portion 146 over the fifth bonding pad 152 such that the second solder material portion 146 is in contact with the fifth bonding pad 152 and with the first film 154 (e.g., see FIG. 3D and related description, above).

The intermediate structure 1700 of FIG. 17 may formed from the intermediate structure 1600 of FIG. 16 by bonding the first bonding pad 114 of the second package 104 (e.g., see FIGS. 1A and 3E) to the second solder material portion 146. In this regard, the second package 104 may be aligned relative to the first package 102 such that the first bonding pads 114 are aligned with the second solder material portions 146 (e.g., see FIG. 1A). A reflow operation may then be performed to reflow the second solder material portions 146 such that a metallurgical bond may be formed between the second solder material portions 146 and the first bonding pads 114, and between the second solder material portions 146 and the fifth bonding pads 152, as shown in FIG. 3E, and described in greater detail, above.

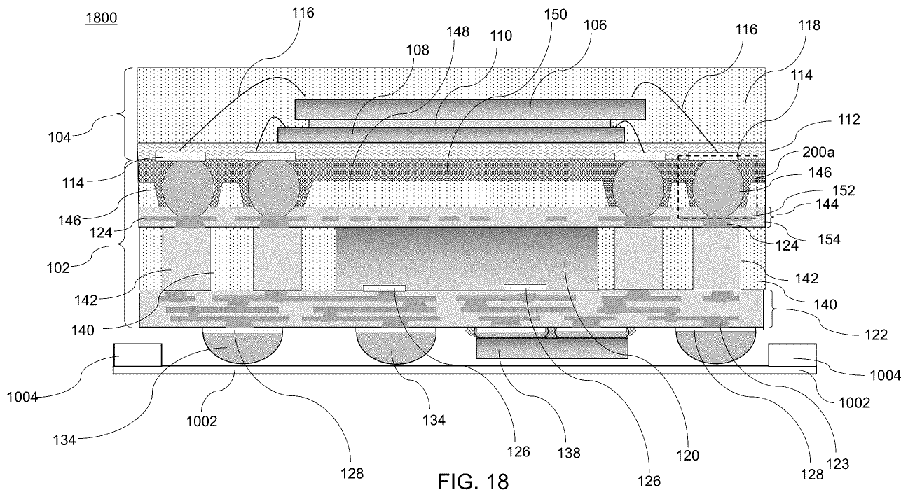

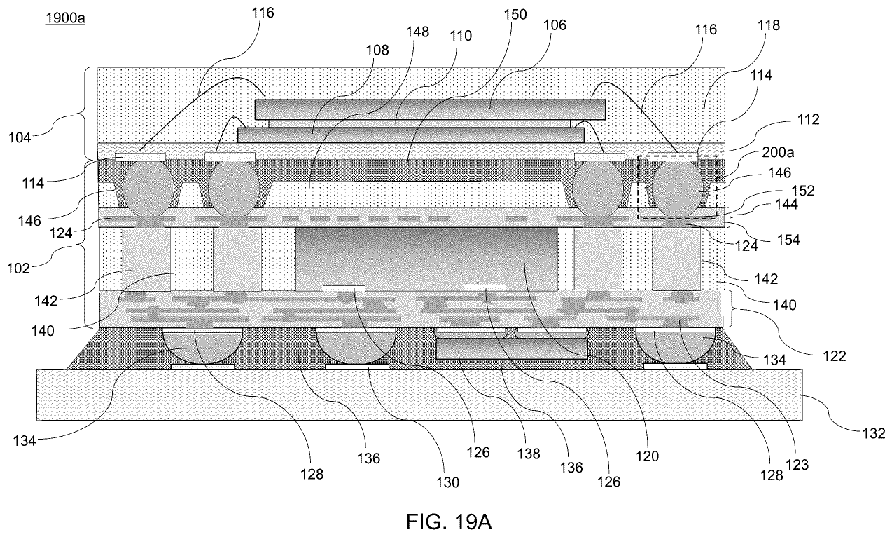

The intermediate structure 1800 of FIG. 18 may formed from the intermediate structure 1700 of FIG. 17 by forming the second underfill material 150 between a bottom surface of the second package 104 (e.g., between a bottom surface of the first bonding pads 114) and a top surface of the first package 102 as shown, for example, in FIGS. 2A and 3E. Lastly, the semiconductor device (1900a, 1900b) may be formed from the intermediate structure 1800 by removing the tape carrier 1002 from the first solder material portions 134. The resulting structure may then be positioned relative the second substrate 132 such that the first solder material portions 134 may be aligned with respective fourth bonding pads 130 of the second substrate 132. A reflow operation may then be formed to bond the first solder material portions 134 to the t fourth bonding pads 130 of the second substrate 132. The first underfill material 136 may then be formed between a bottom surface of the interposer 122 and a top surface of the second substrate 132 thereby completing the formation of the semiconductor device (1900a, 1900b). As shown, the second package 104 may have width that is similar to the first package 102 (e.g., see FIG. 19A) or may have a different (e.g., smaller) width than the first package (e.g., see FIG. 19B).

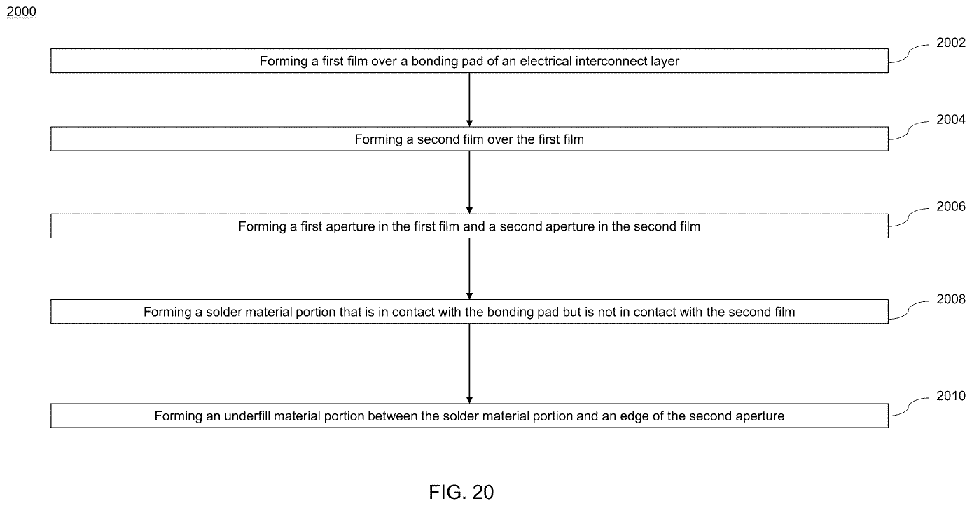

FIG. 20 is a flowchart illustrating operations of a method 2000 of forming a bonding structure 200a (e.g., see FIGS. 2A, 19A, and 19B) for a semiconductor device (1900a, 1900b), according to various embodiments. In operation 2002, the method 2000 may include forming a first film 154 over a bonding pad 152 of an electrical interconnect layer 124 (e.g., see FIGS. 1A, 1B, 2A, and related description, above). In operation 2004, the method 2000 may include forming a second film 148 over the first film 154. In operation 2006, the method 2000 may include forming a first aperture 304 in the first film and a second aperture 306 in the second film such that the first aperture 304 exposes a portion of the bonding pad 152, and the second aperture 306 is formed over the first aperture 304 such that the first aperture 304 is located entirely below an area of the second aperture 306 (e.g., see FIGS. 3B and 3C).

In operation 2008, the method 2000 may include forming a solder material portion 146 that is in contact with the bonding pad 152 but is separated from the second film 148 (e.g., see FIGS. 3D, 3E, and 16 to 19B). In operation 2010, the method 2000 may include forming an underfill material portion 150 between the solder material portion 146 and an edge of the second aperture (e.g., see FIGS. 2A, 18, and 19B).

In operation 2006 of forming the first aperture 304 and the second aperture 306, the method 2000 may further include exposing the first film 154 and the second film 148 to laser radiation 302 to remove a portion of the first film 154 and a portion of the second film 148 to thereby generate the first aperture 304 and the second aperture 306 (e.g., see FIGS. 3B, 3C, and related description, above). Regarding the process of exposing the first film 154 and the second film 148 to laser radiation, in operation 2006, the method 2000 may further include performing a first laser drilling process (e.g., see FIG. 3B) to generate the first aperture 304 in the first film 154 and to generate the second aperture 306 in the second film 148, and performing a second laser drilling process (e.g., see FIG. 3C) to increase a width of the second aperture 306.

Referring to all drawings and according to various embodiments of the present disclosure, a semiconductor device (1900a, 1900b) (see FIGS. 2A, 2B, 19A, and 19B) is provided. The semiconductor device (1900a, 1900b) may include an electrical interconnect layer 124; a bonding pad 152 (e.g. see FIG. 2A) electrically coupled to the electrical interconnect layer 124; a stacked film structure including a first film 154 partially covering a surface of the bonding pad 152 (e.g., see FIGS. 3B and 3C) and a second film 148 partially covering the first film; a first aperture 304 formed in the first film 154 over a portion of the surface of the bonding pad 152 (e.g., see FIGS. 3B and 3C); a second aperture 306 formed in the second film 148 such that the second aperture 306 is larger than the first aperture 304 and is formed over the first aperture 304 such that the first aperture 304 is located entirely below an area of the second aperture 306 (e.g., see FIGS. 3B and 3C); and a solder material portion 146 formed in contact with the bonding pad 152.

The solder material portion 146 may include a fifth width 328 (see FIG. 3D) that is less than a size of the second aperture 306 such that the solder material portion 146 does not contact the second film (e.g., see FIGS. 3D and 3E). The solder material portion 146 may further have a sixth width 330 (e.g., see FIG. 3D) that is comparable to a size of the first aperture 304 such that the solder material portion 146 is in contact with the first film 154. The semiconductor device (1900a, 1900b) may further include an underfill material portion 150 (e.g., see FIGS. 2A, 2B, 19A, and 19B) formed between the solder material portion 146 and an edge of the second aperture 306. The first film 154 may include a polymer material and the second film 148 may include an epoxy material (e.g., see FIG. 1B and related description, above).

The semiconductor device (1900a, 1900b) may further include a first package 102 including a first semiconductor die 120. The electrical interconnect layer 124 (e.g., of the interposer 122) may be electrically coupled to the first semiconductor die 120 (e.g., see FIG. 8 and related description, above). The electrical interconnect layer 124 may also be formed as part of a redistribution layer 144 on a first side of the first package 102. In some embodiments first semiconductor die may be configured as a system-on-chip die (e.g., see FIG. 1A and related description). The first aperture 304 may include a first width 310 that is an a range from approximately 100 microns to approximately 300 microns, and the second aperture 306 may include a second width 312 that is in a range from approximately 110 microns to approximately 500 microns. As shown, for example, in FIGS. 3B and 3C, one or both of the first aperture 304 and the second aperture 306 may have a tapered surface having a taper angle 308 in a range from approximately 0 degrees to 50 degrees

The first package 102 may further include a molding material 140 that partially or completely encloses the first semiconductor die 120 within the first package 102, and a through-molding-material via 142 formed within the molding material 140, such that the through-molding-material via 142 is electrically connected to the bonding pad 152. The first package 102 may further include an interposer 122 formed on a second side of the first package 102, such that the interposer 122 may be electrically coupled to one or both of the first semiconductor die 120 and the through-molding-material via 142. The semiconductor device (1900a, 1900b) may further include a second package 104 including a second semiconductor die (e.g., first memory die 106 and/or second memory die 108). Further, the second package 104 may be electrically coupled to the solder material portion 146. The second film 148 may have a film modulus greater than 3 GPa, a fracture toughness greater than 0.5 MPa m½, and a film coefficient of thermal expansion (CTE) greater than 10 ppm/° C.

In other embodiments, a further semiconductor device (1900a, 1900b) is provided. The semiconductor device (1900a, 1900b) may include a first package 102 including a first semiconductor die 120 and a first bonding pad 152 electrically coupled to the first semiconductor die 120 (e.g., the bonding pad 152 may be electrically coupled to the redistribution layer 144, to the through-molding-material vias 142, to the interposer 122, and to the first semiconductor die 120), a second package 104 including a second semiconductor die (e.g., the first memory die 106 and/or the second memory die 108) and a second bonding pad 114 electrically coupled to the second semiconductor die (106, 108), and a solder material portion 146 electrically connecting the first bonding pad 152 (e.g., see FIG. 2A) of the first package 102 to the second bonding pad 114 of the second package 104.

The first package 102 may further include a stacked film structure including a first film 154 partially covering a surface of the first bonding pad 152 and a second film 148 partially covering the first film 154, such that the second film 148 is separated from the solder material portion 146 (e.g., see FIGS. 2A, 19A, and 19B). The semiconductor device (1900a, 1900b) may further include a first aperture 304 formed in the first film 154 over a portion of the surface of the first bonding pad 152, and a second aperture 306 formed in the second film 148 such that the second aperture 306 is larger than the first aperture 304 and is formed over the first aperture 304 such that the first aperture 304 is located entirely below an area of the second aperture 306 (e.g., see FIGS. 3B and 3C). The first aperture 304 may include a first width 310 that is an a range from approximately 100 microns to approximately 300 microns, and the second aperture 306 may include a second width 312 that is in a range from approximately 110 microns to approximately 500 microns. As shown, for example, in FIGS. 3B and 3C, one or both of the first aperture 304 and the second aperture 306 may have a tapered surface having a taper angle 308 in a range from approximately 0 degrees to 50 degrees. The semiconductor device (1900a, 1900b) may further include an underfill material portion 150 formed between the solder material portion 146 and an edge of the second aperture 306 (e.g., see FIGS. 2A, 2B, 19A, and 19B).

The disclosed embodiments may provide advantages over existing semiconductor devices by providing a package bonding structure that includes a multi-layer film structure. The multilayer film structure may reduce or mitigate cracking and delamination caused by differences in coefficients of thermal expansion between various components of the bonding structure. In this regard, a solder material portion may electrically and mechanically couple a bonding pad of a first package with a bonding pad of a second package. A first film may partially cover the bonding pad of the first package and may be in contact with the solder material portion. A second film may provide mechanical strength to the first package but may be configured to not contact the solder material portion. Rather, an underfill material portion may be formed between the second film and the solder material portion. This configuration may reduce various thermally induced stresses and strains within the bonding structure and may thereby reduce or mitigate cracking and delamination.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
an electrical interconnect layer;
a bonding pad electrically coupled to the electrical interconnect layer;
a stacked film structure comprising a first film partially covering a surface of the bonding pad and a second film partially covering the first film;
a first aperture formed in the first film over a portion of the surface of the bonding pad;
a second aperture formed in the second film such that the second aperture is larger than the first aperture and is formed over the first aperture such that the first aperture is located entirely below an area of the second aperture; and
a solder material portion formed in contact with the bonding pad, wherein the solder material portion comprises a first width that is less than a size of the second aperture such that the solder material portion does not contact the second film.

2. The semiconductor device of claim 1, wherein the solder material portion comprises a second width that is similar to a size of the first aperture such that the solder material portion is in contact with the first film.

3. The semiconductor device of claim 1, further comprising an underfill material portion formed between the solder material portion and an edge of the second aperture.

4. The semiconductor device of claim 1, wherein the first film comprises a polymer material and the second film comprises an epoxy material.

5. The semiconductor device of claim 1, further comprising:
a first package comprising a first semiconductor die,
wherein the electrical interconnect layer is electrically coupled to the first semiconductor die,
wherein the electrical interconnect layer is formed as part of a redistribution layer on a first side of the first package, and
wherein the first semiconductor die is configured as a system-on-chip die.

6. The semiconductor device of claim 1, wherein the first aperture comprises a first width that is an a range from approximately 100 microns to approximately 300 microns, and
wherein the second aperture comprises a second width that is in a range from approximately 110 microns to approximately 500 microns.

7. The semiconductor device of claim 1, wherein one or both of the first aperture and the second aperture comprise a tapered surface having a taper angle in a range from approximately 0 degrees to 50 degrees.

8. The semiconductor device of claim 6, wherein the first package further comprises:
a molding material that partially or completely encloses the first semiconductor die within the first package; and
a through-molding-material via formed within the molding material, wherein the through-molding-material via is electrically connected to the bonding pad.

9. The semiconductor device of claim 8, wherein the first package further comprises:
an interposer formed on a second side of the first package, wherein the interposer is electrically coupled to one or both of the first semiconductor die and the through-molding-material via.

10. The semiconductor device of claim 5, further comprising:
a second package comprising a second semiconductor die, wherein the second package is electrically coupled to the solder material portion.

11. The semiconductor device of claim 1, wherein the second film comprises a film modulus greater than 3 GPa, a fracture toughness greater than 0.5 MPa m^{1/2}, and a film coefficient of thermal expansion greater than 10 ppm/° C.

12. A semiconductor device, comprising:
a first semiconductor package comprising a first semiconductor die and a first bonding pad electrically coupled to the first semiconductor die;
a second semiconductor package comprising a second semiconductor die and a second bonding pad electrically coupled to the second semiconductor die; and
a solder material portion electrically connecting the first bonding pad of the first semiconductor package to the second bonding pad of the second semiconductor package,
wherein the first semiconductor package further comprises a stacked film structure comprising a first film partially covering a surface of the first bonding pad and a second film partially covering the first film, and
wherein the second film is separated from the solder material portion.

13. The semiconductor device of claim 12, further comprising:
a first aperture formed in the first film over a portion of the surface of the first bonding pad; and
a second aperture formed in the second film such that the second aperture is larger than the first aperture and is formed over the first aperture such that the first aperture is located entirely below an area of the second aperture.

14. The semiconductor device of claim 13, wherein the first aperture comprises a first width that is an a range from approximately 100 microns to approximately 300 microns, and
wherein the second aperture comprises a second width that is in a range from approximately 110 microns to approximately 500 microns.

15. The semiconductor device of claim 13, wherein one or both of the first aperture and the second aperture comprise a tapered surface having a taper angle in a range from approximately 0 degrees to 50 degrees.

16. The semiconductor device of claim 13, further comprising an underfill material portion formed between the solder material portion and an edge of the second aperture.

17. A method of forming a bonding structure for a semiconductor device, comprising:
forming a first film over a bonding pad of an electrical interconnect layer;
forming a second film over the first film;
forming a first aperture in the first film and a second aperture in the second film such that the first aperture exposes a portion of the bonding pad, and the second aperture is formed over the first aperture such that the first aperture is located entirely below an area of the second aperture; and
forming a solder material portion that is in contact with the bonding pad but is separated from the second film.

18. The method of claim 17, further comprising:
forming an underfill material portion between the solder material portion and an edge of the second aperture.

19. The method of claim 17, wherein forming the first aperture and the second aperture further comprises exposing the first film and the second film to laser radiation to remove a portion of the first film and a portion of the second film to thereby generate the first aperture and the second aperture.

20. The method of claim 19, wherein exposing the first film and the second film to laser radiation further comprises:
performing a first laser drilling process to generate the first aperture in the first film and to generate the second aperture in the second film; and
performing a second laser drilling process to increase a width of the second aperture.
